(19) United States
(12) Patent Application Publication
(10) Pub. No.: US 2023/0179885 A1
(43) Pub. Date: Jun. 8, 2023

(54) Methods and Systems for Processing of Microscopy Images

(71) Applicant: FEI Company, Hillsboro, OR (US)

(72) Inventors: Jeroen KEIZER, Eindhoven (NL); Francis-Paul JANSSEN, Eindhoven (NL); Jacob Simon FABER, Eindhoven (NL)

(73) Assignee: FEI Company, Hillsboro, OR (US)

(21) Appl. No.: 17/545,928

(22) Filed: Dec. 8, 2021

(51) Int. Cl. H04N 5/378; H01J 37/244; H01J 37/26; H04N 5/341; H01J 37/147

(52) U.S. Cl. CPC H04N 5/378; H01J 37/244; H01J 37/263; H04N 5/341; H01J 37/1471

(57) ABSTRACT

Techniques for acquiring an electron energy loss spectrum in two dimensions are disclosed herein. The technique at least includes exposing an electron sensor to an electron spectrum projected in two dimensions, wherein one of the two dimensions corresponds to a dispersive axis, and the other of the two dimensions corresponds to a non-dispersive axis, receiving an electron sensor readout frame from the electron sensor, where the electron sensor readout frame comprises a plurality of values representative of the electron spectrum in each of the two dimensions, and reducing a resolution of the electron sensor readout frame in at least one of the two dimensions, where reducing the resolution includes reducing the number of values in the at least one of the two dimensions, where the electron sensor readout frame comprises a plurality of values in each of the two dimensions after the reduction in resolution.

### FIELD OF THE INVENTION

The present invention relates generally to the field of microscopy. More particularly, it relates to a method for enhancing and improving the process of extracting information from a microscopy image.

### BACKGROUND OF THE INVENTION

In an exemplary microscopy system, a beam of particles is directed on to a sample. The beam of particles may comprise photons or charged particles like electrons or ions. Particles in the beam interact with particles in the sample leading to a variety of different emissions including photons, or charged particles such as electrons. These emissions may be captured by a detector sub-system of the microscopy system and may be processed to generate images of the sample, for example.

The detector sub-system may comprise, for example, an electron energy loss spectrometer (EELS) that can be configured to detect an energy spectrum of the electrons comprising the emissions described above. The electron energy loss spectrometer may comprise an energy offset drift tube, wherein a magnetic field may be applied to the electrons emitted from the sample to cause them to get separated based on their kinetic energy. Thus, the beam of electrons may be separated into electrons of different energies along a dimension (or direction) that may be called a dispersive direction (or dimension or axis). The dispersive direction may be significantly perpendicular to the direction of velocity of the electrons and the direction of the applied magnetic field.

An electron sensor, that may be a direct electron sensor or an indirect electron sensor, may be configured to be used together with an electron energy loss spectrometer, wherein the electron sensor may capture/readout frames comprising locations where an electron has been detected by the sensor. The location along the dispersive axis where an electron is detected may comprise information about the energy of the electron that may then be used to infer something about the interaction between the electron beam and the particles of the sample, and thus draw inference about the sample.

A relevant consideration when using such sensors may be a balance between the rate at which data is collected and processed on the one hand and dynamic range and sensor lifetime on the other. Incident currents in the range of pico-Amps at localized regions of the electron sensor are common. These correspond to many millions of electrons per pixel per second at the electron sensor. Such high incidence of electrons may adversely affect the lifetime of the sensor. Additionally, using the full height of the sensor to detect electrons may significantly increase the data readout time. Thus, the area of the sensor over which electrons may be detected may be reduced. However, this may lead to shortening of the dynamic range. A possible solution to this problem is to spread the spectrum in a direction significantly orthogonal to the incident beam and to the dispersive axis. This may be called a non-dispersive direction (or dimension or axis). This may decrease the incident intensity but at the cost of higher readout time and noise as the same spectrum is spread out over more pixels.

U.S. Pat. No. 10,535,492 B2 discloses a method to use the full detector optimally and efficiently. The method comprises projecting the detected 2-dimensional electron spectrum along the non-dispersive axis into a 1-dimensional electron spectrum and only transmitting the 1-dimensional spectrum to an external device for further processing. While this may help reduce the time taken for sensor readout and any readout noise it also results in a loss of information contained in the non-dispersive dimension of the 2-dimensional electron spectrum. In particular, as will be described below, the non-dispersive dimension may contain information relating to the alignment of the electron beam which is lost in the projection process.

Embodiments of the present invention are particularly directed to improving the process of acquiring an electron energy spectrum and to increasing the amount of information extracted from the non-dispersive dimension of the electron spectrum. While they are described with an exemplary electron beam microscopy system, it should be understood that at least some of the embodiments described herein may also be used in fields different from electron beam microscopy.

The present invention seeks to overcome or at least alleviate the shortcomings and disadvantages of the prior art. More particularly, it is an object of the present invention to provide an improved method, system, and computer program product for acquiring an electron spectrum in two dimensions.

### SUMMARY

According to a first aspect, the present invention relates to a microscopy system comprising: an electron sensor configured to detect electrons impinging on the sensor in two dimensions, wherein one of the two dimensions corresponds to a dispersive axis and the other of the two dimensions corresponds to a non-dispersive axis; and a sensor processing unit configured to receive an electron sensor readout frame from the electron sensor, wherein the electron sensor readout frame comprises a plurality of values representative of the electron spectrum in each of the two dimensions, and wherein the sensor processing unit is further configured to reduce a resolution of the electron sensor readout frame in at least one of the two dimensions, wherein reducing the resolution comprises reducing the number of values in at least one of the two dimensions. As described above, such a reduction may be of advantage in enhancing the efficiency of data processing.

The sensor processing unit may be further configured to send the electron sensor readout frame with the reduced resolution. The frame may be sent to an external device for further processing or analysis. The external device may comprise a computer, for example.

The sensor processing unit may be configured to reduce the resolution of the electron sensor readout frame in the dimension corresponding to the non-dispersive axis.

The electron sensor readout frame may comprise a plurality of values in each of the two dimensions after the reduction in resolution. Thus, the electron sensor readout frame may retain its two-dimensional nature even after the reduction in resolution. Or, in other words, the resolution may not be reduced such that the two-dimensional electron sensor readout frame is transformed into a one-dimensional electron spectrum and information about the non-dispersive direction is lost.

The electron sensor may comprise a direct or indirect detection sensor. For example, the electron sensor may comprise any of a CCD camera, a CMOS camera, a hybrid pixel detector, an active pixel sensor, or any other suitable electron sensor.

The sensor processing unit may be further configured to receive a target resolution in any of the two dimensions and it may be further configured to reduce the resolution of the electron sensor readout frame to the target resolution. For example, the electron sensor readout frame as received from the electron sensor may comprise a 100×50 grid and the sensor processing unit may be configured to output electron sensor readout frames with a 100×20 grid. The setting of a target resolution may allow control of the amount of information in the non-dispersive direction retained in the electron sensor readout frames sent out by the sensor processing unit.

The sensor processing unit may be configured to receive a plurality of electron sensor readout frames. This may be of advantage, for example, if the detection rate for the electron sensor is higher than the sensor processing unit's processing rate per readout frame.

The sensor processing unit may be configured to reduce the resolution of a plurality of electron sensor readout frames.

The sensor processing unit may be configured to sum together a plurality of electron sensor readout frames. This may also be of advantage for the example described above, viz., if the detection rate for the electron sensor is higher than the sensor processing unit's processing rate per readout frame. Then, the sensor processing unit may first sum up the plurality of electron sensor readout frames and then reduce the resolution of the summed-up electron sensor readout frame. While the order of summing up and reducing resolution is irrelevant if the sensor processing unit is configured to apply a linear transformation (such as a summation, an average, or a convolution) to the received electron sensor readout frame, the order may be of importance in case a non-linear transformation is applied to the received electron sensor readout frame. In this case, the sensor processing unit may be configured to first reduce the resolution of each of the plurality of electron sensor readout frames (as described above) and then sum them up, or it may first sum them up and then reduce the resolution.

The microscopy system may be further configured to determine a drift of the electron spectrum based on the electron sensor readout frame. The drift may be determined based on, for example, a difference between the electron spectra recorded along two different regions in the non-dispersive direction. In case of a non-zero drift, the two electron spectra may not be identical.

The drift of the electron spectrum may be determined after the resolution of the electron sensor readout frame has been reduced. This may help enhance the efficiency of the drift determination process as a smaller amount of data needs to be processed.

The microscopy system may be further configured to align the electron sensor based on the drift of the electron spectrum. For example, a non-zero drift measured in the electron sensor readout frame as described above may be used as feedback or feedforward to determine the correct alignment of the electron sensor.

The microscopy system may be configured to direct a beam of electrons at a sample and the microscopy system may be configured to align the electron beam based on the drift of the electron spectrum.

In a second aspect, the present invention also relates to a method of acquiring an electron energy loss spectrum in two dimensions, comprising: exposing an electron sensor to an electron spectrum projected in the two dimensions, wherein one of the two dimensions corresponds to a dispersive axis, and the other of the two dimensions corresponds to a non-dispersive axis; receiving an electron sensor readout frame from the electron sensor, wherein the electron sensor readout frame comprises a plurality of values representative of the electron spectrum in each of the two dimensions; and reducing a resolution of the electron sensor readout frame in at least one of the two dimensions, wherein reducing the resolution comprises reducing the number of values in the at least one of the two dimensions.

The method may further comprise sending the electron sensor readout frame after reducing its resolution.

The electron sensor readout frame may comprise a plurality of values in each of the two dimensions after the reduction in resolution.

The reduction in resolution may be carried out in the dimension corresponding to the non-dispersive axis.

The reduction in resolution may comprise summing up, at least in part, the electron spectrum. Summing up may also be understood to comprise averaging, at least in part, the electron spectrum. For example, if the electron sensor readout frame received by the sensor processing unit as described before comprises a 100×50 grid (row major format), and the resolution is desired to be reduced down to a 100×2 grid, the method may comprise averaging over the first 25 pixels to obtain one column of the electron sensor readout frame, and averaging over the second 25 pixels to obtain the second column of the electron sensor readout frame.

The reduction in resolution may comprise convolution of, at least part of, the electron spectrum with a window function. The window function may be chosen appropriately based on the information sought from the electron sensor readout frame. For example, it may comprise a top hat window function with a width of some pixels. Then, the electron sensor readout frame with the reduced resolution may represent the effect of smoothing out/coarse-graining the electron spectrum over a number of pixels proportional to the width of the top hat window function. This may help to determine the average number of electrons detected in any given region. Note however, that embodiments of the present invention are not restricted to only coarse-graining as a method for reducing resolution, but comprise any mathematical many-to-one or many-to-many transformation that may take as input a first number of values and output a second number of values, wherein the first number is greater than the second number.

The method may comprise receiving a plurality of electron sensor readout frames from the electron sensor.

The method may further comprise reducing the resolution of a plurality of electron sensor readout frames.

The method may further comprise summing together a plurality of electron sensor readout frames.

The microscopy system as described above may be configured to perform the method as described above.

In a third aspect, the present invention relates to a use of the method as described above to align an electron beam.

Aligning the electron beam may comprise determining a drift of the electron spectrum based on the electron sensor readout frame. The drift may be determined using the electron sensor frame with the reduced resolution. For example, this may be carried out by the external device to which the electron sensor readout frame is sent after reduction in resolution.

Aligning the electron beam may comprise determining a drift of the electron spectrum based on a plurality of electron sensor readout frames.

Aligning the electron beam may further comprise using the drift as feedback.

Aligning the electron beam may further comprise using the drift as feedforward.

The drift may be determined using a machine learning model.

An input to the machine learning model may comprise the electron sensor readout frame.

An output of the machine learning model may comprise at least one value based on which the electron sensor is aligned.

The use as described above may comprise using the method as described above to align an electron sensor.

In a fourth aspect, the present invention also relates to a computer program product comprising instructions, when run on a data processing unit of a system as described above, to at least carry out a reduction in resolution of at least one electron sensor readout frame.

Embodiments of the present invention will now be described with reference to the accompanying drawings, which should only exemplify, but not limit, the scope of the present invention.

### BRIEF DESCRIPTION OF THE DRAWINGS

FIG. 1 depicts an exemplary microscopy system;

FIG. 2 depicts an embodiment of the method according to the present invention; and

FIG. 3 depicts a further embodiment of the method according to the present invention.

### DETAILED DESCRIPTION OF EMBODIMENTS

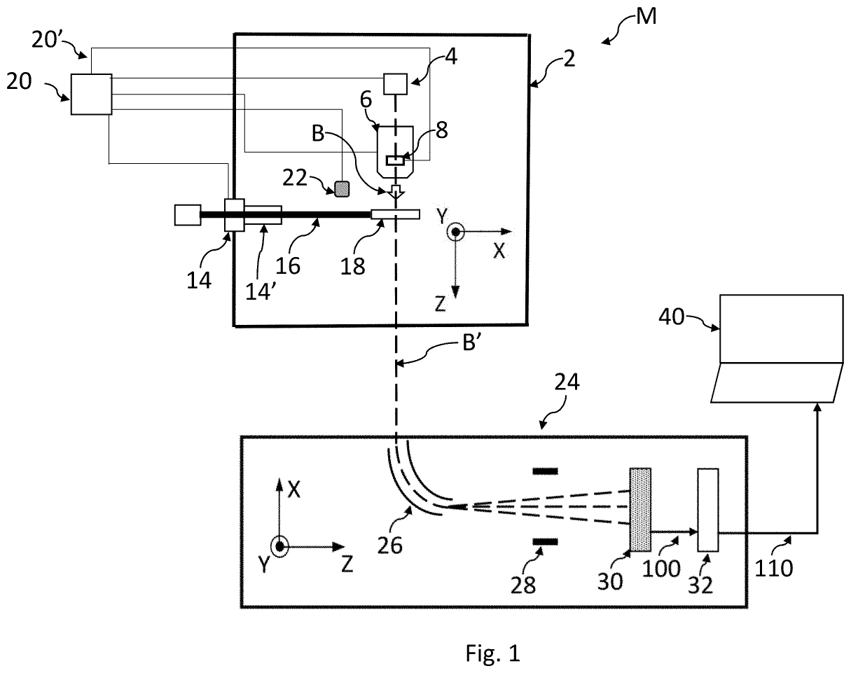

FIG. 1 depicts an embodiment of a microscopy system M, particularly a charged particle microscopy system M configured to use a charged particle beam B to observe and/or characterize a sample 18. The charged particle beam B may comprise electrons or ions. In the particular case depicted in FIG. 1, it comprises electrons. Additionally, the microscopy system M depicted in FIG. 1 may comprise a transmission-type microscopy system M, wherein an image of the sample 18 is taken using the emissions in the transmission region of the microscopy system M. Thus, M may represent a Transmission Electron Microscope (TEM) or a Scanning Transmission Electron Microscope (STEM). In the Figure, within a vacuum enclosure 2, an electron source 4 produces the beam B of electrons that propagates along an electron-optical axis B′ and traverses an electron-optical illuminator 6, serving to direct/focus the electrons onto a chosen part of the sample 18 (which may, for example, be (locally) thinned/planarized).

Also depicted is a deflector 8, which (inter alia) can be used to effect scanning motion of the beam B. The sample 18 may be held on a sample holder i6 that can be positioned in multiple degrees of freedom by a positioning device/stage 14, which moves a cradle 14′ into which holder 16 is (removably) affixed; for example, the sample holder 16 may comprise a finger that can be moved (inter alia) in the XY plane (see the depicted Cartesian coordinate system; typically, motion parallel to Z and tilt about X/Y will also be possible). Such movement allows different parts of the sample 18 to be illuminated/imaged/inspected by the electron beam B traveling along axis B′ (in the Z direction) (and/or allows scanning motion to be performed, as an alternative to beam scanning). If desired, an optional cooling device (not depicted) can be brought into intimate thermal contact with the sample holder 16, so as to maintain it (and the sample 18 thereupon) at cryogenic temperatures, for example.

The electron beam B will interact with the sample 18 in such a manner as to cause various types of “stimulated” radiation to emanate from the sample 18, including (for example) secondary electrons, backscattered electrons, X-rays and optical radiation (cathodoluminescence). If desired, one or more of these radiation types can be detected with the aid of analysis device 22, which might be a combined scintillator/photomultiplier or EDX (Energy-Dispersive X-Ray Spectroscopy) module, for instance; in such a case, an image could be constructed using basically the same principle as in a Scanning Electron Microscope (SEM). However, alternatively or supplementally, one can study electrons that traverse (pass through) the sample 18, exit/emanate from it and continue to propagate (substantially, though generally with some deflection/scattering) along axis B′.

Such a transmitted electron flux enters an imaging system (energy filter) 24, which will generally comprise a variety of electrostatic/magnetic lenses, deflectors, correctors (such as stigmators), etc. In particular, when the microscopy system M is used for electron energy loss spectroscopy, the imaging system 24 may comprise the offset drift tube 26. The offset drift tube 26 may comprise a region where a magnetic field (not shown) may be applied to the electron beam B. The magnetic field may be applied in a direction substantially parallel to the Y-direction in the configuration depicted in FIG. 1 such that the path of the electrons in the beam B is curved in the plane depicted in FIG. 1. The electrons may describe a substantially circular path under the influence of the magnetic force resulting from interaction with the magnetic field B, where the radius of the circular path may be based on the speed of the electron. Electrons with a higher speed travel on a path with a larger radius. Thus, the electron beam is split along the X-direction (the dispersive dimension in the configuration of FIG. 1) at the exit of the offset drift tube 26 depending on the speed (and so, the energy) of the electrons.

The electrons emitted from the offset drift tube 26 may then enter an imaging sub-system 28 that may also comprise a variety of electrostatic/magnetic lenses, deflectors, correctors (such as stigmators), etc. The imaging sub-system 28 may be configured, for example, to cause a spread of the electron beam B in the Y-direction (the non-dispersive dimension in the configuration of FIG. 1) as described above. The 2-dimensional electron spectrum 100, representative of the electron energy spectrum, may then be acquired by an electron sensor 30. The electron sensor 30 may comprise a direct or indirect detection sensor. The electron sensor 30 may comprise a significantly 2-dimensional receiving section comprising a plurality of pixels over which the 2-dimensional electron spectrum, that is acquired as the 2-dimensional electron spectrum 100, may be incident. The sensor 30 may be configured to detect the pixel location on which a number of electrons in excess of a threshold number are incident. This may correspond to a detection of electrons at that pixel location.

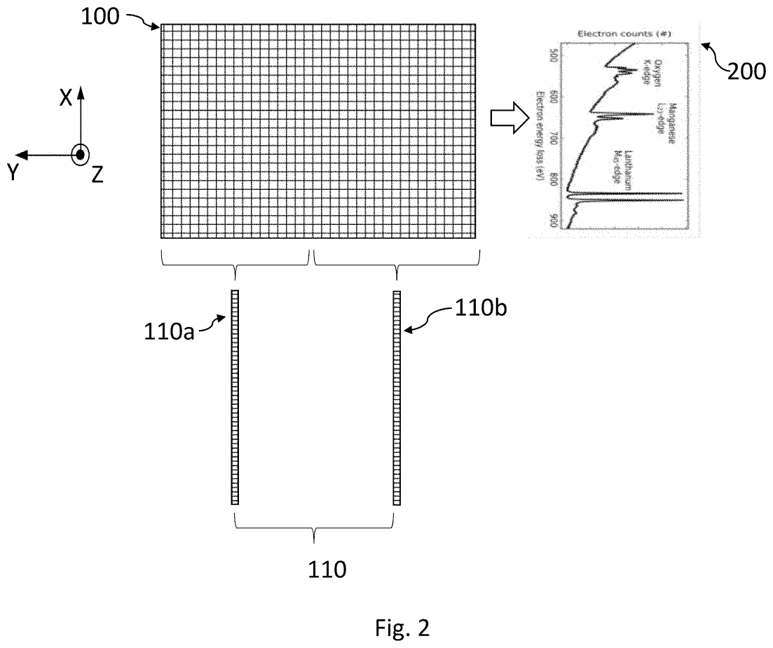

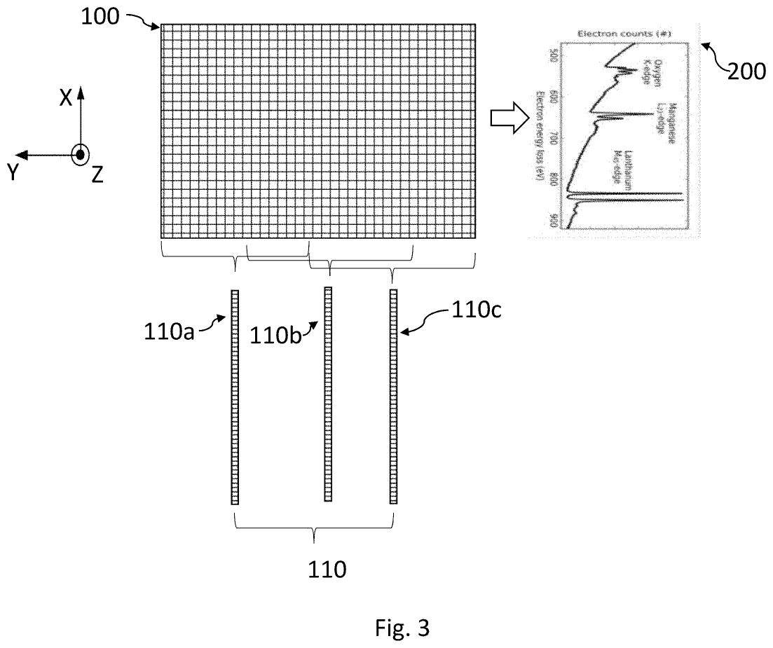

The sensor 30 may send the 2-dimensional electron spectrum 100 to a sensor processor, that may also be called a sensor processing unit, 32. The 2-dimensional electron spectrum 100 (that may also be called an electron sensor readout frame or simply a sensor readout frame) may comprise a plurality of values in each of the two dimensions corresponding to a dispersive dimension (X) and a non-dispersive dimension (Y). Note that the Z-direction has been chosen to correspond to the optic axis, or the direction in which the electron beam propagates. Consequently, while the Z axis points in the vertically downward direction in the vacuum enclosure 2, it gets rotated by the offset drift tube 26 to point in the horizontally right direction in the imaging system 24 and later on. FIGS. 2 and 3 then depict a view looking down at the electron beam, for example, from behind the electron sensor 30.

The sensor processor 32 may be configured to reduce a resolution of the 2-dimensional sensor readout frame 100 without significant processing overhead. The sensor processor 32 may also be configured to send the sensor readout frame 110 with the reduced resolution to an external device 40, wherein the external device 40 may comprise, for example, a computer, a tablet, a laptop, a smartphone, or any other data processing device. Further, the sensor processor 32 may be configured to reduce the resolution of the 2-dimensional electron spectrum 100 by reducing the number of values representative of the electron spectrum in at least one of the two dimensions corresponding to the dispersive and non-dispersive dimensions. Preferably, the sensor processor 32 may reduce the resolution in the non-dispersive dimension. The number of values representative of the electron spectrum in each of the two dimensions corresponding to the dispersive and non-dispersive dimensions of the electron sensor readout frame no may be greater than 1 after the reduction in resolution by the sensor processor 32.

For example, the sensor 30 may send a sensor readout frame 100 comprising a total of 50 values in a 5×10 grid in the X-Y plane corresponding to the number of electrons detected at 50 pixels of the sensor 30. Thus, the readout frame 100 comprises values representative of the electron spectrum in 10 energy bands (along to the X-direction) and 5 bands along the non-dispersive direction (along the Y-direction). The sensor processor 32 may then be configured to reduce the resolution of this frame 100 to a 2×10 grid in the X-Y plane representing an electron spectrum 110 in 10 energy bands but only 2 bands in the non-dispersive direction. Since the sensor processor 32 may only reduce the resolution of an input electron sensor readout frame loo and output the electron sensor readout frame 110 with the reduced resolution, it may be configured to have a frame processing rate substantially identical to the rate at which electrons are detected by the sensor 30.

Note that a controller (that may be a computer processor) 20 is connected to various illustrated components via control lines (buses) 20′. This controller 20 can provide a variety of functions, such as synchronizing actions, providing setpoints, processing signals, performing calculations, and displaying messages/information on a display device (not depicted). Needless to say, the (schematically depicted) controller 20 may be (partially) inside or outside the enclosure 2, and may have a unitary or composite structure, as desired. The skilled artisan will understand that the interior of the enclosure 2 does not have to be kept at a strict vacuum; for example, in a so-called “Environmental TEM/STEM”, a background atmosphere of a given gas is deliberately introduced/maintained within the enclosure 2. The skilled artisan will also understand that, in practice, it may be advantageous to confine the volume of enclosure 2 so that, where possible, it essentially hugs the axis B′, taking the form of a small tube (e.g., of the order of 1 cm in diameter) through which the employed electron beam passes, but widening out to accommodate structures such as the source 4, sample holder 16, offset drift tube 26, sensor 30, sensor processor 32, etc.

FIG. 2 depicts an exemplary embodiment of a 2-dimensional electron sensor readout frame loo as detected by the sensor 30 (shown in FIG. 1). The 2-dimensional electron sensor readout frame 100 comprises a two-dimensional grid of values in the X-Y plane that may correspond to electron counts detected by the sensor 30 at different pixels represented by the squares of the grid in frame 100. The X-axis may correspond to an energy direction with energy loss depicted as being lower for increasing X in a projected 1-dimensional electron energy loss spectrum 200. The Y-axis may correspond to the number of electrons detected at different locations of the sensor 30 with an energy given by the corresponding position along the X-direction. As described above, the sensor readout frame 100 may be projected along the non-dispersive (Y) direction to obtain the one-dimensional electron energy loss spectrum 200 depicting the electron counts as a function of the electron energy loss. However, this may lead to a loss of information contained in the electron counts (numbers) recorded along the non-dispersive (Y) direction.

According to an embodiment of the present invention as depicted in FIG. 2, the loss of information may be reduced by reducing a resolution of the sensor readout frame 100, instead of projecting it into a one-dimensional spectrum. The two columns labeled 110a, 110b represent two columns of a two-dimensional spectrum 110 that may be obtained by reducing the resolution of the sensor readout frame 100. In this particular embodiment, the resolution has been reduced so as to obtain a two-dimensional spectrum 110 comprising only 2 values in the non-dispersive dimension and the same number of values as the sensor readout frame 100 in the dispersive dimension. It will be understood that the resolution may be reduced so as to obtain a larger number of values in the non-dispersive dimension, for example, 3 values as depicted in FIG. 3, for each value of electron energy. In particular, the present invention is directed to reduction of resolution without complete loss of information contained in the non-dispersive dimension. As such, the two-dimensional spectrum 110 obtained after the reduction of resolution comprises a plurality of values in each of the dispersive and non-dispersive dimensions. Additionally, with only a minimal overhead in terms of amount of data transferred to the external processing device 40, it also provides for an efficient method of using the information contained in the spectrum in the non-dispersive dimension.

The reduction in the number of values (that may also be called reduction in resolution as described above) may be carried out by any of summing up, averaging, convolving with a window function, and any other (many-to-one or many-to-many) mathematical transformation of the values in the dimension in which the resolution is reduced. Further, any two sets of values that may be mathematically transformed, as described above, into values representative of the electron spectrum (with the reduced resolution) may be disjoint, or may have a non-zero intersection, i.e., the reduction in resolution may be performed by transforming regions of the electron sensor readout frame 100 that may or may not be disjoint.

For example, in the embodiment depicted in FIG. 2 the resolution of the electron sensor readout frame 100 is reduced such that two disjoint regions of the electron sensor readout frame 100 are mapped to two disjoint regions of the electron sensor readout frame 110 with reduced resolution. However, FIG. 3 depicts another embodiment where three partially overlapping regions of the electron sensor readout frame 100 are mapped on to three disjoint regions of the electron sensor readout frame 110 with reduced resolution. In particular, a first region is mapped on to the column depicted as 110a, a second region that partially overlaps with the first region and with a third region is mapped on to the column depicted as 110b, and the third region that partially overlaps with the second region is mapped on to a third column 110c. The three columns 110a, 110b, and 110c together comprise the electron sensor readout frame 110 with reduced resolution.

Embodiments of the present invention may be of particular advantage in alignment of the electron beam B and/or the electron sensor 30 (as shown in FIG. 1). For example, if the beam B and the sensor 30 are misaligned, the electron sensor readout frame 110 after reduction in resolution may depict an asymmetry in the non-dispersive dimension. Or, the electron sensor readout frame 110 may be used to determine a drift of the electron spectrum. This drift may be used to correct for any misalignment of the electron beam B and/or the electron sensor 30. Note that in the absence of the second (non-dispersive) dimension this information would be lost.

By making use of features characteristic of a misalignment in the 2-dimensional sensor readout frame 110 even with the reduced resolution, the alignment may be corrected. Such features may be identified by visual inspection by human or automatically by means of a computer-implemented method. The computer-implemented method may comprise, for example, an artificial intelligence-based method that may accept the sensor readout frame 110 as an input and that may produce a measure of misalignment such as a drift of the electron spectrum, or a measure of correction such as an angle by which the electron beam B or the electron sensor 30 may be tilted, as an output. The artificial intelligence-based method may comprise, at least in part, any of a neural network, such as a deep convolutional neural network, a recurrent neural network, or any other architecture of neural network, a random forest, a gradient boosting machine, a support vector machine, or any other artificial intelligence-based model. The artificial intelligence-based method may be trained appropriately by, for example, varying the alignment of the electron beam B and/or the electron sensor 30 and acquiring the electron sensor readout frame 110 for each position of alignment. The output of the computer-implemented method (or also the visual inspection described above) may be used either as feedback or feedforward into the microscopic system M, preferably the controller 20 of the microscopic system M, to correct for the misalignment.

Further, for example, the electron sensor readout frame 110 with the reduced resolution may be convolved with a step function along the non-dispersive axis such that a difference between the spectra along the non-dispersive axis is effectively calculated. The result of this convolution may be used as an input for a feedback control that controls the electron sensor 30 or the beam deflection in the non-dispersive direction. The controller may be an artificial intelligence-based PID controller or may employ any other suitable control method. Thus, a shift/drift of the electron spectrum may be detected not only in a direction orthogonal to the dispersive axis but also at an angle. Additionally, multiple electron spectra may be correlated to determine an angle that may be used for feedback or feedforward leading to improvement in the energy resolution or a modulation transfer function (characteristic of the resolution and performance of the microscopy system M) of the microscopy system M.

Overall, embodiments of the present technology thus provide a method to enhance the amount of information that may be extracted from a microscopic image, preferably an electron microscopic image, that is robust and efficient.

Whenever a relative term, such as “about”, “substantially” or “approximately” is used in this specification, such a term should also be construed to also include the exact term. That is, e.g., “substantially straight” should be construed to also include “(exactly) straight”.

Whenever steps were recited in the above or also in the appended claims, it should be noted that the order in which the steps are recited in this text may be accidental. That is, unless otherwise specified or unless clear to the skilled person, the order in which steps are recited may be accidental. That is, when the present document states, e.g., that a method comprises steps (A) and (B), this does not necessarily mean that step (A) precedes step (B), but it is also possible that step (A) is performed (at least partly) simultaneously with step (B) or that step (B) precedes step (A). Furthermore, when a step (X) is said to precede another step (Z), this does not imply that there is no step between steps (X) and (Z). That is, step (X) preceding step (Z) encompasses the situation that step (X) is performed directly before step (Z), but also the situation that (X) is performed before one or more steps (Y1), . . . , followed by step (Z). Corresponding considerations apply when terms like “after” or “before” are used.

While in the above, a preferred embodiment has been described with reference to the accompanying drawings, the skilled person will understand that this embodiment was provided for illustrative purpose only and should by no means be construed to limit the scope of the present invention, which is defined by the claims.

The present invention is also defined by the following numbered embodiments.

Below system embodiments will be discussed. These embodiments are abbreviated by the letter ‘S’ followed by a number. Whenever reference is herein made to system embodiments, these embodiments are meant.

S1. A microscopy system comprising:
an electron sensor configured to detect electrons impinging on the sensor in two dimensions, wherein one of the two dimensions corresponds to a dispersive axis and the other of the two dimensions corresponds to a non-dispersive axis; and
a sensor processing unit configured to receive an electron sensor readout frame from the electron sensor, wherein the electron sensor readout frame comprises a plurality of values representative of the electron spectrum in each of the two dimensions, and wherein the sensor processing unit is further configured to reduce a resolution of the electron sensor readout frame in at least one of the two dimensions, wherein reducing the resolution comprises reducing the number of values in at least one of the two dimensions.

S2. The microscopy system according to the preceding embodiment, wherein the sensor processing unit is further configured to send the electron sensor readout frame with the reduced resolution.

S3. The microscopy system according to any of the preceding system embodiments, wherein the sensor processing unit is configured to reduce the resolution of the electron sensor readout frame in the dimension corresponding to the non-dispersive axis.

S4. The microscopy system according to any of the preceding system embodiments, wherein the electron sensor readout frame comprises a plurality of values in each of the two dimensions after the reduction in resolution.

S5. The microscopy system according to any of the preceding system embodiments, wherein the electron sensor comprises a direct detection sensor.

S6. The microscopy system according to any of the preceding system embodiments but without the features of the preceding embodiment, wherein the electron sensor comprises an indirect detection sensor.

S7. The microscopy system according to any of the preceding system embodiments, wherein the sensor processing unit is further configured to receive a target resolution in any of the two dimensions, and wherein it is further configured to reduce the resolution of the electron sensor readout frame to the target resolution.

S8. The microscopy system according to any of the preceding system embodiments, wherein the sensor processing unit is configured to receive a plurality of electron sensor readout frames.

S9. The microscopy system according to the preceding embodiment, wherein the sensor processing unit is configured to reduce the resolution of a plurality of electron sensor readout frames.

S10. The microscopy system according to any of the 2 preceding embodiments, wherein the sensor processing unit is configured to sum together a plurality of electron sensor readout frames.

S11. The microscopy system according to any of the preceding system embodiments, wherein the microscopy system is further configured to determine a drift of the electron spectrum based on the electron sensor readout frame.

S12. The microscopy system according to the preceding embodiment, wherein the drift of the electron spectrum is determined after the resolution of the electron sensor readout frame has been reduced.

S13. The microscopy system according to any of the 2 preceding embodiments, wherein the microscopy system is further configured to align the electron sensor based on the drift of the electron spectrum.

S14. The microscopy system according to any of the 3 preceding embodiments, wherein the microscopy system is configured to direct a beam of electrons at a sample, and wherein the microscopy system is configured to align the electron beam based on the drift of the electron spectrum.

Below method embodiments will be discussed. These embodiments are abbreviated by the letter ‘M’ followed by a number. Whenever reference is herein made to method embodiments, these embodiments are meant.

M1. A method of acquiring an electron energy loss spectrum in two dimensions, comprising:
exposing an electron sensor to an electron spectrum projected in the two dimensions, wherein one of the two dimensions corresponds to a dispersive axis, and the other of the two dimensions corresponds to a non-dispersive axis;
receiving an electron sensor readout frame from the electron sensor, wherein the electron sensor readout frame comprises a plurality of values representative of the electron spectrum in each of the two dimensions; and
reducing a resolution of the electron sensor readout frame in at least one of the two dimensions, wherein reducing the resolution comprises reducing the number of values in the at least one of the two dimensions.

M2. The method according to the preceding embodiment, wherein the method further comprises sending the electron sensor readout frame after reducing its resolution.

M3. The method according to any of the 2 preceding embodiments, wherein the electron sensor readout frame comprises a plurality of values in each of the two dimensions after the reduction in resolution.

M4. The method according to any of the preceding method embodiments, wherein the reduction in resolution is carried out in the dimension corresponding to the non-dispersive axis.

M5. The method according to any of the preceding method embodiments, wherein the reduction in resolution comprises summing up, at least in part, the electron spectrum.

M6. The method according to any of the preceding method embodiments, wherein the reduction in resolution comprises convolution of, at least part of, the electron spectrum with a window function.

M7. The method according to any of the preceding method embodiments, wherein the method comprises receiving a plurality of electron sensor readout frames from the electron sensor.

M8. The method according to the preceding embodiment, wherein the method further comprises reducing the resolution of a plurality of electron sensor readout frames.

M9. The method according to any of the 2 preceding embodiments, wherein the method further comprises summing together a plurality of electron sensor readout frames.

S15. The microscopy system according to any of the preceding system embodiments, wherein the microscopy system is configured to perform the method according to any of the preceding method embodiments.

Below use embodiments will be discussed. These embodiments are abbreviated by the letter ‘U’ followed by a number. Whenever reference is herein made to use embodiments, these embodiments are meant.

U1. Use of the method according to any of the preceding method embodiments to align an electron beam.

U2. The use according to the preceding embodiment, wherein aligning the electron beam comprises determining a drift of the electron spectrum based on the electron sensor readout frame.

U3. The use according to the preceding embodiment, wherein aligning the electron beam comprises determining a drift of the electron spectrum based on a plurality of electron sensor readout frames.

U4. The use according to any of the preceding use embodiments and with the features of embodiment U2, wherein aligning the electron beam further comprises using the drift as feedback.

U5. The use according to any of the preceding use embodiments and with the features of embodiment U2, wherein aligning the electron beam further comprises using the drift as feedforward.

U6. The use according to any of the preceding use embodiments and with the features of embodiment U2, wherein the drift is determined using a machine learning model.

U7. The use according to the preceding embodiment, wherein an input to the machine learning model comprises the electron sensor readout frame.

U8. The use according to any of the 2 preceding embodiments, wherein an output of the machine learning model comprises at least one value based on which the electron sensor is aligned.

U9. The use according to any of the preceding use embodiments, wherein the use comprises using the method according to any of the preceding method embodiments to align an electron sensor.

Below computer program product embodiments will be discussed. These embodiments are abbreviated by the letter ‘P’ followed by a number. Whenever reference is herein made to computer program product embodiments, these embodiments are meant.

P1. A computer program product comprising instructions, when run on a data processing unit of a system according to any of the preceding system embodiments, to at least carry out a reduction in resolution of at least one electron sensor readout frame.

1. A method of acquiring an electron energy loss spectrum in two dimensions, comprising:
exposing an electron sensor to an electron spectrum projected in the two dimensions, wherein one of the two dimensions corresponds to a dispersive axis, and the other of the two dimensions corresponds to a non-dispersive axis;
receiving an electron sensor readout frame from the electron sensor, wherein the electron sensor readout frame comprises a plurality of values representative of the electron spectrum in each of the two dimensions; and
reducing a resolution of the electron sensor readout frame in at least one of the two dimensions, wherein reducing the resolution comprises reducing the number of values in the at least one of the two dimensions, and wherein the electron sensor readout frame comprises a plurality of values in each of the two dimensions after the reduction in resolution.

2. The method according to the preceding claim, wherein the method further comprises sending the electron sensor readout frame after reducing its resolution.

3. The method according to claim 1, wherein the reduction in resolution is carried out in the dimension corresponding to the non-dispersive axis.

4. The method according to claim 1, wherein the reduction in resolution comprises summing up, at least in part, the electron spectrum.

5. The method according to claim 1, wherein the reduction in resolution comprises convolution of, at least part of, the electron spectrum with a window function.

6. The method according to claim 1, wherein the method comprises receiving a plurality of electron sensor readout frames from the electron sensor.

7. The method according to claim 6, wherein the method further comprises summing together a plurality of electron sensor readout frames.

8. A microscopy system comprising:
an electron sensor configured to detect electrons impinging on the sensor in two dimensions, wherein one of the two dimensions corresponds to a dispersive axis and the other of the two dimensions corresponds to a non-dispersive axis; and
a sensor processing unit configured to receive an electron sensor readout frame from the electron sensor, wherein the electron sensor readout frame comprises a plurality of values representative of the electron spectrum in each of the two dimensions, and wherein the sensor processing unit is further configured to reduce a resolution of the electron sensor readout frame in at least one of the two dimensions, wherein reducing the resolution comprises reducing the number of values in at least one of the two dimensions, and wherein the electron sensor readout frame comprises a plurality of values in each of the two dimensions after the reduction in resolution.

9. The microscopy system according to claim 8, wherein the electron sensor comprises a direct detection sensor.

10. The microscopy system according to claim 8, wherein the electron sensor comprises an indirect detection sensor.

11. The microscopy system according to claim 8, wherein the sensor processing unit is further configured to receive a target resolution in any of the two dimensions, and wherein it is further configured to reduce the resolution of the electron sensor readout frame to the target resolution.

12. Use of the method according to claim 1 to align an electron beam.

13. The use according to claim 12, wherein aligning the electron beam comprises determining a drift of the electron spectrum based on the electron sensor readout frame.

14. The use according to claim 13, wherein aligning the electron beam further comprises using the drift as feedback.

15. The use according to claim 13, wherein aligning the electron beam further comprises using the drift as feedforward.

16. The use according to claim 12, wherein the use further comprises aligning an electron sensor.
